(19) United States
(12) Patent Application Publication
(10) Pub. No.: US 2026/0064000 A1
(43) Pub. Date: Mar. 5, 2026

(54) RESIST UNDERLAYER COMPOSITION, AND METHOD OF FORMING PATTERNS USING THE COMPOSITION

(71) Applicant: SAMSUNG SDI CO., LTD., Yongin-si (KR)

(72) Inventors: Hwayoung JIN, Suwon-si (KR); Ahra CHO, Suwon-si (KR); Eunsu LEE, Suwon-si (KR); Soojeung KIM, Suwon-si (KR); Jungin MUN, Suwon-si (KR); Sungwoo JUNG, Suwon-si (KR); Yoojeong CHOI, Suwon-si (KR); Jihye LEE, Suwon-si (KR)

(21) Appl. No.: 19/303,631

(22) Filed: Aug. 19, 2025

(30) Foreign Application Priority Data
Aug. 29, 2024 (KR) 10-2024-0117149

(51) Int. Cl. G03F 7/039; G03F 7/09

(52) U.S. Cl. CPC G03F 7/0397; G03F 7/09

(57) ABSTRACT

A resist underlayer composition, a method of forming a pattern utilizing the resist underlayer composition, a system of forming a pattern utilizing the resist underlayer composition, and a resist underlayer of the resist underlayer composition are disclosed. The resist underlayer composition may include a polymer including a structural unit represented by Chemical Formula 1 and a structural unit represented by Chemical Formula 2 and a solvent.

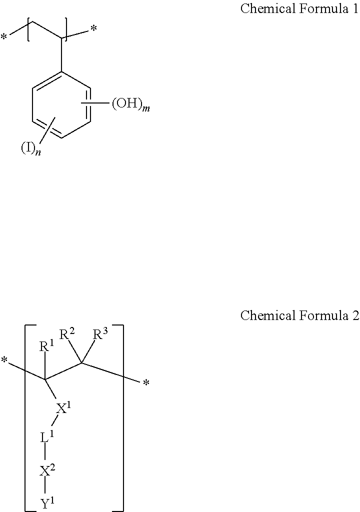

### CROSS-REFERENCE TO RELATED APPLICATION

The present application claims priority to and the benefit of Korean Patent Application No. 10-2024-0117149, filed on Aug. 29, 2024, in the Korean Intellectual Property Office, the entire content of which is incorporated herein by reference.

### BACKGROUND

### 1. Field

One or more embodiments of the present disclosure relate to a resist underlayer composition and a method of forming a pattern utilizing the resist underlayer composition.

### 2. Description of the Related Art

The semiconductor industry has recently advanced to ultra-fine patterning techniques, with pattern sizes ranging from several nanometers to several tens of nanometers in size. These ultra-fine techniques desire, require, and/or need highly effective lithographic processes.

A lithographic technique or lithography is a process that includes coating a photoresist film onto a semiconductor substrate, such as a silicon wafer, to form a thin film; irradiating the photoresist film with activating radiation (e.g., ultraviolet light (UV)) through a mask bearing a device pattern; developing the exposed film to form a photoresist pattern; and etching the substrate utilizing the photoresist pattern as a mask to form a fine pattern on the substrate surface.

As semiconductor patterns continue to shrink, thinner photoresist layers are desired or required. Consequently, the resist underlayer should also be thin. Despite its reduced thickness, the resist underlayer should still maintain sufficient mechanical strength to support the photoresist pattern, exhibit good adhesion to the photoresist, and be formed with uniform thickness. Additionally, the resist underlayer should have a high refractive index and a low extinction coefficient for the light utilized in photolithography, as well as a faster etch rate than the photoresist layer.

### SUMMARY

One or more aspects of embodiments of the present disclosure are directed toward a resist underlayer composition which provides a resist underlayer in which pattern collapse of the resist does not occur (or a degree or occurrence of pattern collapse of the resist is reduced) even in a fine patterning process and sensitivity to an exposure light source is improved or enhanced, thereby improving or enhancing patterning performance and energy efficiency.

One or more aspects of embodiments of the present disclosure are directed toward a method of forming a pattern utilizing the resist underlayer composition.

Additional aspects of embodiments will be set forth in part in the description which follows and, in part, will be apparent from the description or may be learned by practice of the presented embodiments of the disclosure.

A resist underlayer composition according to one or more embodiments includes a polymer including a structural unit represented by Chemical Formula 1 and a structural unit represented by Chemical Formula 2 and a solvent:

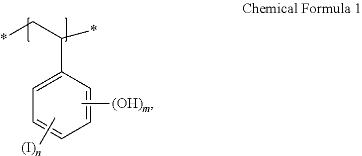

wherein, in Chemical Formula 1,
m is one of integers of 1 to 4,
n is one of integers of 1 to 4,
m+n is an integer less than or equal to 5, and
* is a linking point;

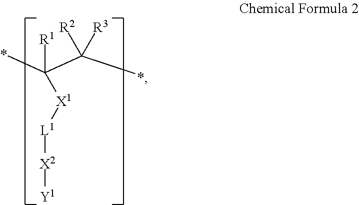

wherein, in Chemical Formula 2,
L¹ is a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C3 to C20 heterocycloalkylene group, a substituted or unsubstituted C6 to C20 arylene group, or a combination thereof,
X¹ and X² are each independently a single bond (e.g., a single covalent bond), —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ is a group represented by Chemical Formula 3,
R¹ to R³ are each independently hydrogen, deuterium, or a substituted or unsubstituted C1 to C10 alkyl group, and
* is a linking point:

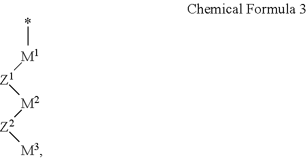

wherein, in Chemical Formula 3,
M¹ is a single bond (e.g., a single covalent bond), a substituted or unsubstituted C1 to C20 alkylene group, a substituted or unsubstituted C2 to C20 alkenylene group, —O—, —NH—, or a combination thereof,
Z¹ and Z² are each independently —C(═O)— or —CH(OH)—,
M² is a single bond (e.g., a single covalent bond), a double bond (e.g., a carbon-carbon double bond), *—C(R^{b})═* (wherein, R^{b} is hydrogen, deuterium, or a C1 to C5 alkyl group, and * is a linking point with Z¹ or Z²), or a substituted or unsubstituted C1 to C3 alkylene group,
M³ is a hydroxyl group, a substituted or unsubstituted C1 to C20 alkyl group, a substituted or unsubstituted C2 to C20 alkenyl group, or a substituted or unsubstituted C6 to C20 aryl group,
M¹ and M³ or M² and M³ are optionally linked with (e.g., linked to) each other to form a ring, and
* is a linking point.

In Chemical Formula 1, m and n may each independently be 1 or 2.

In Chemical Formula 3, L¹ may be a single bond (e.g., a single covalent bond) or a substituted or unsubstituted C1 to C10 alkylene group, and X¹ and X² may each independently be a single bond (e.g., a single covalent bond) or —(CO)O—.

In the polymer, the structural unit represented by Chemical Formula 1 and the structural unit represented by Chemical Formula 2 may be present in a molar ratio of about 9:1 to about 1:9.

The polymer may further include a structural unit represented by Chemical Formula 4:

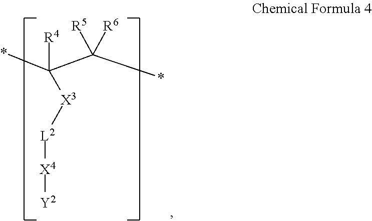

wherein, in Chemical Formula 4,
L² may be a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X³ and X⁴ may each independently be a single bond (e.g., a single covalent bond), —O—, —S—, —S(═O)—, —S(═O)₂—, —C(═O)—, —(CO)O—, —O(CO)O—, —C(═O)NH—, —NR^{c}— (wherein, R^{c} is hydrogen, deuterium, or a C1 to C10 alkyl group), or a combination thereof,
Y² may be a hydroxyl group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, or a substituted or unsubstituted C6 to C20 aryl group,
R⁴ to R⁶ may each independently be hydrogen, deuterium, or a substituted or unsubstituted C1 to C10 alkyl group, and
* may be a linking point.

In Chemical Formula 4, L² may be a single bond (e.g., a single covalent bond), a substituted or unsubstituted C1 to C10 alkylene group, or a substituted or unsubstituted C6 to C10 arylene group, X³ and X⁴ may each independently be a single bond (e.g., a single covalent bond) or —(CO)O—, and Y² may be a hydroxyl group, a substituted or unsubstituted C1 to C10 alkyl group, a substituted or unsubstituted C2 to C20 heterocycloalkyl group, or a substituted or unsubstituted C6 to C20 aryl group.

Chemical Formula 2 may be represented by one or more selected from among Chemical Formula 2-1 to Chemical Formula 2-8:

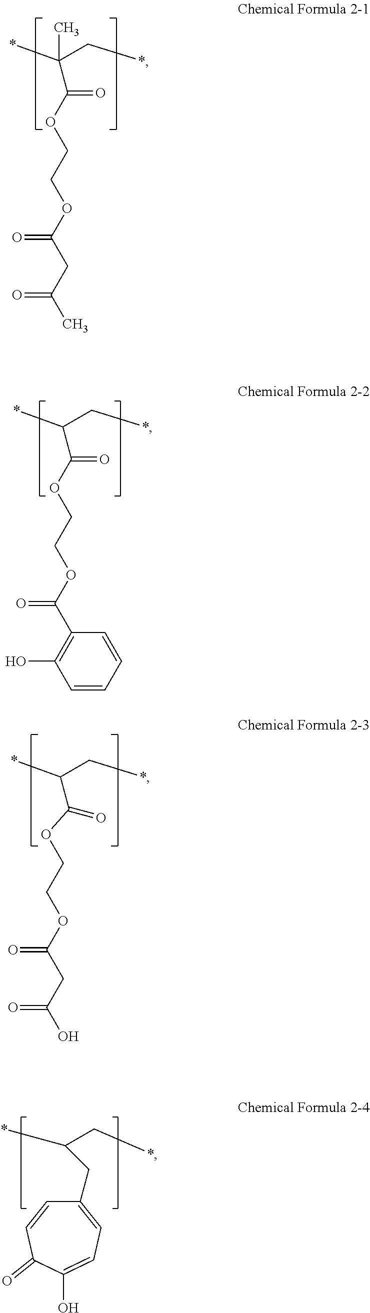

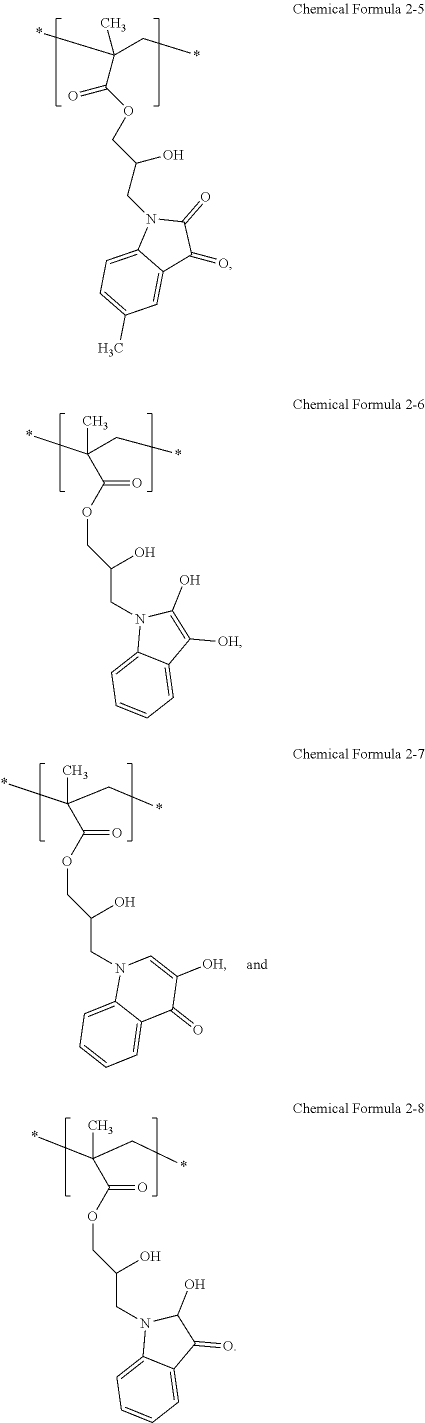

A weight average molecular weight (M_{w}) of the polymer may be from about 1,000 g/mol to about 300,000 g/mol.

The polymer may be included in an amount of about 0.1 wt % to about 50 wt % based on a total weight (e.g., based on 100 wt %) of the resist underlayer composition.

The composition may further include one or more polymers selected from among an acrylic resin, an epoxy resin, a novolac-based resin, a glycoluril-based resin, and a melamine-based resin.

The composition may further include an additive of a surfactant, a thermal acid generator, a photoacid generator, a plasticizer, or a combination thereof.

According to one or more embodiments, a method of forming a pattern includes forming an etching target layer on a substrate, forming a resist underlayer by applying the resist underlayer composition according to one or more embodiments on the etching target layer, forming a photoresist pattern on the resist underlayer, and sequentially etching the resist underlayer and the etching target layer utilizing the photoresist pattern as an etching mask.

According to one or more embodiments, a system of forming a pattern includes: means for forming an etching target layer on a substrate; means for forming a resist underlayer by applying the resist underlayer composition as described in one or more embodiments on the etching target layer; means for forming a photoresist pattern on the resist underlayer; and means for sequentially etching the resist underlayer and the etching target layer utilizing the photoresist pattern as an etching mask.

One or more embodiments of the present disclosure provide a resist underlayer of the resist underlayer composition as described in one or more embodiments.

The resist underlayer composition according to one or more embodiments may provide a resist underlayer in which pattern collapse of the resist does not occur (or a degree or occurrence of pattern collapse of the resist is reduced) even in a fine patterning process and sensitivity to an exposure light source may be improved or enhanced, thereby enabling improved or enhanced patterning performance and energy efficiency. For example, the resist underlayer may effectively or suitably suppress or prevent pattern collapse of the photoresist, even during fine patterning processes involving sub-10 nm features. This is achieved through the tailored design of the polymer structure, which includes specific functional groups and linkages that enhance mechanical strength, film uniformity, and interfacial adhesion. Additionally, the composition may exhibit improved or enhanced sensitivity to exposure light sources, thereby enabling reduced exposure doses and enhanced energy efficiency. These characteristics contribute to improved or enhanced lithographic performance, including better critical dimension control, reduced line edge roughness, and higher pattern fidelity.

Furthermore, the resist underlayer composition may be formulated to exhibit a high refractive index and a low extinction coefficient at the exposure wavelength, which enhances the optical contrast and resolution of the photoresist pattern. The composition may also be engineered to have a higher etch rate than the photoresist, facilitating selective removal during pattern transfer processes. These properties make the composition suitable for utilization in advanced semiconductor manufacturing.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1F are cross-sectional views illustrating a method of forming a pattern utilizing a resist underlayer composition according to one or more embodiments.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive.

The utilization of “may” if (e.g., when) describing embodiments of the present disclosure refers to “one or more embodiments of the present disclosure.”

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items. Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” or “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

In the drawings, the thickness of layers, films, panels, regions, and/or the like may be exaggerated for clarity, and like reference numerals designate like elements throughout the attached drawings and the written description, and duplicative descriptions thereof may not be provided in the specification.

It will be understood that if (e.g., when) an element, such as a layer, a film, a region, or a substrate, is referred to as being “on” or “above” another element, it may be directly on or above the other element or intervening elements may also be present therebetween. In contrast, if (e.g., when) an element is referred to as being “directly on” or “directly above” another element, there are no intervening elements present therebetween.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, 20%, 10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

As used herein, if (e.g., when) a definition is not otherwise provided, “substituted” refers to replacement of a hydrogen atom of a compound by a substituent selected from among deuterium, halogen (e.g., F, Br, Cl, or I), a hydroxyl group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

Also, two adjacent substituents of the substituted halogen atom (e.g., F, Br, Cl, or I), hydroxyl group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, “heterocyclic group” includes a heteroaryl group and a cyclic group including at least one heteroatom selected from among N, O, S, P, and Si instead of carbon (C) of a cyclic compound, such as an aryl group, a cycloalkyl group, a fused ring thereof, or a combination thereof. If (e.g., when) the heterocyclic group is a fused ring, each or entire ring of the heterocyclic group may include at least one heteroatom.

For example, the substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiphenyl group, a substituted or unsubstituted carbazolyl group, a substituted or unsubstituted pyridoindolyl group, a substituted or unsubstituted benzopyridooxazinyl group, a substituted or unsubstituted benzopyridothiazinyl group, a substituted or unsubstituted 9,9-dimethyl-9,10-dihydroacridinyl group, a combination thereof, or a combined fused ring of the foregoing groups, but embodiments of the present disclosure are not limited thereto.

As used herein, if (e.g., when) specific definition is not otherwise provided, the term “combination” refers to mixing or copolymerization.

Also, as used herein, “polymer” may include both (e.g., simultaneously) oligomers and polymers.

Unless otherwise specified in the present disclosure, the weight average molecular weight (M_{w}) is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

Also, unless otherwise defined in the specification, “*” indicates a linking point of a structural unit or a moiety of a polymer.

In the semiconductor industry, it is desirable to reduce the size of chips. In order to meet this requirement, a line width of the resist patterned in lithography technology is desired to be reduced to a level of several tens of nanometers, and the pattern formed in this way may be utilized to transfer the pattern to a lower material by utilizing an etching process on a lower substrate. However, as the pattern size of the resist becomes smaller, a height (e.g., aspect ratio) of the resist that can withstand the line width is limited, and accordingly, the resists may not have sufficient or suitable resistance in the etching step (e.g., act or task). Therefore, a resist underlayer has been utilized to compensate for this detriment if (e.g., when) a thin resist material is utilized, if (e.g., when) the substrate to be etched is thick, and/or if (e.g., when) a deep pattern is desired or required.

The resist underlayer is desired or required to become thinner as the thickness of the resist becomes thinner, and the photoresist pattern is desired not to collapse even if (e.g., when) the resist underlayer is thin. For this purpose, the resist underlayer is desired to have excellent or suitable adhesion to the photoresist. Also, in forming a thin resist underlayer, coating uniformity of the resist underlayer composition and flatness of the resist underlayer produced therefrom are desired to be improved or enhanced, and sensitivity to the exposure light source is desired to be improved or enhanced to improve or enhance pattern formability and energy efficiency.

The resist underlayer composition according to one or more embodiments may include a polymer including a structural unit represented by Chemical Formula 1 and a structural unit represented by Chemical Formula 2 and a solvent:

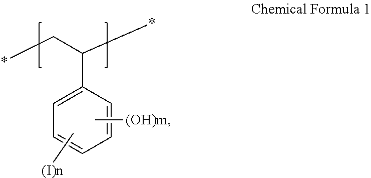

wherein, in Chemical Formula 1,
m may be one of integers of 1 to 4,
n may be one of integers of 1 to 4,
m+n may be an integer less than or equal to 5, and
* may be a linking point;

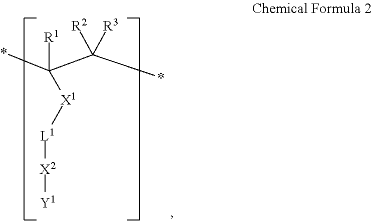

wherein, in Chemical Formula 2,
L¹ may be a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C3 to C20 heterocycloalkylene group, a substituted or unsubstituted C6 to C20 arylene group, or a combination thereof,
X¹ and X² may each independently be a single bond (e.g., a single covalent bond), —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ may be a group represented by Chemical Formula 3,
R¹ to R³ may each independently be hydrogen, deuterium, or a substituted or unsubstituted C1 to C10 alkyl group, and
* may be a linking point:

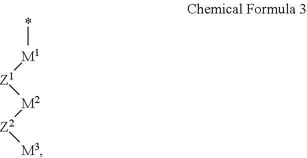

wherein, in Chemical Formula 3,
M¹ may be a single bond (e.g., a single covalent bond), a substituted or unsubstituted C1 to C20 alkylene group, a substituted or unsubstituted C2 to C20 alkenylene group, —O—, —NH—, or a combination thereof,
Z¹ and Z² may each independently be —C(═O)— or —CH(OH)—,
M² may be a single bond (e.g., a single covalent bond), a double bond (e.g., a carbon-carbon double bond), *—C(R^{b})═* (wherein, R^{b} is hydrogen, deuterium, or a C1 to C5 alkyl group, and * is a linking point with Z¹ or Z²), or a substituted or unsubstituted C1 to C3 alkylene group,
M³ may be a hydroxyl group, a substituted or unsubstituted C1 to C20 alkyl group, a substituted or unsubstituted C2 to C20 alkenyl group, or a substituted or unsubstituted C6 to C20 aryl group,
M¹ and M³ or M² and M³ may optionally be linked with (e.g., linked to) each other to form a ring, and
* may be a linking point.

The polymer included in a resist underlayer composition according to one or more embodiments may include the structural unit represented by Chemical Formula 1 and the structural unit represented by Chemical Formula 2. The structural unit represented by Chemical Formula 1 may include a benzene ring and an iodine (I) atom, may have high light absorption efficiency, and may improve or enhance the sensitivity of the polymer if (e.g., when) exposed to light. The structural unit represented by Chemical Formula 2 may include the group represented by Chemical Formula 3 at the terminal, and the group represented by Chemical Formula 3 may include two or more —(C═O)— or —CH(OH)— groups in adjacent positions, thereby being capable of forming a coordination bond with an inorganic material in the photoresist. Accordingly, the close contacting property between the resist underlayer formed from the composition including the polymer and the photoresist film may be increased or enhanced.

In Chemical Formula 1, m may be, for example, one of the integers of 1 to 4, for example, one of the integers of 1 to 3, 1 or 2, or 1. In one or more embodiments, n may be, for example, one of the integers of 1 to 4, for example, one of the integers of 1 to 3, 2 or 3, or 2. In one or more embodiments, m+n may be less than or equal to 5, and may be, for example, one of the integers of 2 to 4, for example, 3.

In Chemical Formula 2, X¹ and X² may, for example, each independently, be a single bond (e.g., a single covalent bond), —O—, —C(═O)—, or —(CO)O—, for example, a single bond (e.g., a single covalent bond) or —(CO)O—, but embodiments of the present disclosure are not limited thereto.

In Chemical Formula 2, L¹ may be, for example, a single bond (e.g., a single covalent bond), a substituted or unsubstituted C1 to C10 alkylene group, or a substituted or unsubstituted C2 to C10 alkenylene group, for example, a single bond (e.g., a single covalent bond) or a substituted or unsubstituted C1 to C10 alkylene group, for example, a single bond (e.g., a single covalent bond) or substituted C1 to C10 alkylene group, for example, a single bond (e.g., a single covalent bond) or a C1 to C5 alkylene group substituted with a hydroxyl group, but embodiments of the present disclosure are not limited thereto.

In Chemical Formula 2, R¹ to R³ may be, for example, hydrogen, deuterium, or a substituted or unsubstituted C1 to C5 alkyl group, and may be, for example, hydrogen, a methyl group, or an ethyl group, but embodiments of the present disclosure are not limited thereto.

In Chemical Formula 3, M¹ may be, for example, a single bond (e.g., a single covalent bond), a substituted or unsubstituted C1 to C10 alkylene group, a substituted or unsubstituted C2 to C10 alkenylene group, —O—, —NH—, or a combination thereof, for example, a single bond (e.g., a single covalent bond), a substituted or unsubstituted C1 to C5 alkylene group, a substituted or unsubstituted C2 to C5 alkenylene group, —O—, —NH—, or a combination thereof, for example, a substituted or unsubstituted C1 to C5 alkylene group, —NH—, for example, a combination of —O— and a C1 to C5 alkylene group, for example, a combination of —O— and a C2 to C5 alkenylene group, but embodiments of the present disclosure are not limited thereto.

In Chemical Formula 3, Z¹ and Z² may each independently be —C(═O)— or —CH(OH)—, for example, Z¹ and Z² may each be —C(═O)—, for example, Z¹ and Z² may each be —CH(OH)—, for example, one selected from Z¹ and Z² may be —C(═O)— and the other may be —CH(OH)—.

In Chemical Formula 3, M² may be a single bond (e.g., a single covalent bond), a double bond (e.g., a carbon-carbon double bond), *—C(R^{b})═* (wherein, R^{b} is hydrogen, deuterium, or a C1 to C5 alkyl group), or a substituted or unsubstituted C1 to C3 alkylene group, and, for example, a single bond (e.g., a single covalent bond), a double bond (e.g., a carbon-carbon double bond), *—CH═*, *—C(CH₃)═*, or a substituted or unsubstituted methylene group, and, for example, a single bond (e.g., a single covalent bond), a double bond (e.g., a carbon-carbon double bond), *—CH═*, or a substituted or unsubstituted methylene group, but embodiments of the present disclosure are not limited thereto. In *—C(R^{b})═*, * may be a linking point with Z¹ or Z².

If (e.g., when) M² has a larger number of carbon atoms than the number of carbons as described in one or more embodiments, the distance between Z¹ and Z² may become larger, making it difficult to effectively or suitably form a coordination bond with an inorganic material in the photoresist, and thus the close contacting property between the photoresist film and the resist underlayer may not be high. For example, if (e.g., when) M² is a single bond (e.g., a single covalent bond), a double bond (e.g., a carbon-carbon double bond), *—C(R^{b})═*, or a substituted or unsubstituted C1 to C3 alkylene group, the close contacting property of the resist underlayer and the photoresist film manufactured from the polymer may be effectively or suitably increased or enhanced.

In Chemical Formula 3, M³ may be a hydroxyl group, a substituted or unsubstituted C1 to C20 alkyl group, a substituted or unsubstituted C2 to C20 alkenyl group, or a substituted or unsubstituted C6 to C20 aryl group, for example, a hydroxyl group, a substituted or unsubstituted C1 to C10 alkyl group, a substituted or unsubstituted C2 to C10 alkenyl group, or a substituted or unsubstituted C6 to C10 aryl group, for example, a hydroxyl group, a substituted or unsubstituted C1 to C5 alkyl group, a substituted or unsubstituted C2 to C5 alkenyl group, or a substituted or unsubstituted phenyl group, but embodiments of the present disclosure are not limited thereto.

M¹ and M³ or M² and M³ of Chemical Formula 3 may each independently be linked to each other to form a ring. For example, M¹ and M³ of Chemical Formula 3 may be optionally linked to each other to form a ring, or M² and M³ may be optionally linked to each other to form a ring. For example, M¹ and M³ may each independently be present, and M¹ and M³ may be linked to each other to form a ring, and M² and M³ may each independently be present, and M² and M³ may be linked to each other to form a ring.

In the polymer, a molar ratio of the structural unit represented by Chemical Formula 1 to the structural unit represented by Chemical Formula 2 may be about 9:1 to about 1:9, for example, about 8:2 to about 2:8, about 7:3 to about 2:8, about 6:4 to about 2:8, about 5:5 to about 2:8, about 8:2 to about 3:7, about 8:2 to about 4:6, or about 8:2 to about 5:5, but embodiments of the present disclosure are not limited thereto. By including the foregoing structural units in the foregoing ratio in the polymer, the light absorption efficiency and/or sensitivity of the resist underlayer composition according to one or more embodiments may be easily or suitably controlled or selected, and the surface roughness and degree of planarization of the resist underlayer manufactured thereby may be improved (or enhanced) or optimized.

According to one or more embodiments, a resist underlayer composition may further include a structural unit represented by Chemical Formula 4:

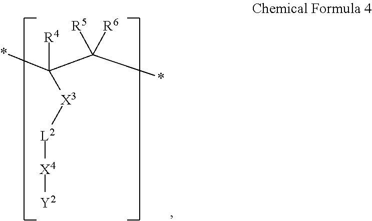

wherein, in Chemical Formula 4,
L² may be a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X³ and X⁴ may each independently be a single bond (e.g., a single covalent bond), —O—, —S—, —S(═O)—, —S(═O)₂—, —C(═O)—, —(CO)O—, —O(CO)O—, —C(═O)NH—, —NR^{c}— (wherein, R^{c} is hydrogen, deuterium, or a C1 to C10 alkyl group), or a combination thereof,
Y² may be a hydroxyl group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, or a substituted or unsubstituted C6 to C20 aryl group,
R⁴ to R⁶ may each independently be hydrogen, deuterium, or a substituted or unsubstituted C1 to C10 alkyl group, and
* may be a linking point.

In Chemical Formula 4, L² may be, for example, a single bond (e.g., a single covalent bond), a substituted or unsubstituted C1 to C10 alkylene group, a substituted or unsubstituted C2 to C10 alkenylene group, or a substituted or unsubstituted C6 to C10 arylene group, for example, a single bond (e.g., a single covalent bond), a substituted or unsubstituted C1 to C10 alkylene group or a substituted or unsubstituted C6 to C10 arylene group, for example, a single bond (e.g., a single covalent bond) or a substituted or unsubstituted C1 to C5 alkylene group, but embodiments of the present disclosure are not limited thereto.

In Chemical Formula 4, X³ and X⁴ may each independently be, for example, a single bond (e.g., a single covalent bond), —O—, —C(═O)—, —S—, —S(═O)—, —S(═O)₂—, or —(CO)O—, for example, a single bond (e.g., a single covalent bond) or —(CO)O—, but embodiments of the present disclosure are not limited thereto.

In Chemical Formula 4, Y² may be, for example, a hydroxyl group, a substituted or unsubstituted C1 to C10 alkyl group, a substituted or unsubstituted C2 to C10 alkenyl group, a substituted or unsubstituted C2 to C20 heterocycloalkyl group, or a substituted or unsubstituted C6 to C20 aryl group, for example, a hydroxyl group, a substituted or unsubstituted C1 to C10 alkyl group, a substituted or unsubstituted C2 to C20 heterocycloalkyl group, or a substituted or unsubstituted C6 to C20 aryl group, for example, a hydroxyl group, a substituted or unsubstituted C1 to C5 alkyl group, or a substituted or unsubstituted C2 to C10 heterocycloalkyl group, but embodiments of the present disclosure are not limited thereto.

In Chemical Formula 4, R⁴ to R⁶ may each independently be hydrogen, deuterium, or a substituted or unsubstituted C1 to C10 alkyl group, for example, hydrogen, deuterium, or a substituted or unsubstituted C1 to C5 alkyl group, but embodiments of the present disclosure are not limited thereto.

For example, Chemical Formula 2 may be represented by one or more selected from among Chemical Formula 2-1 to Chemical Formula 2-8:

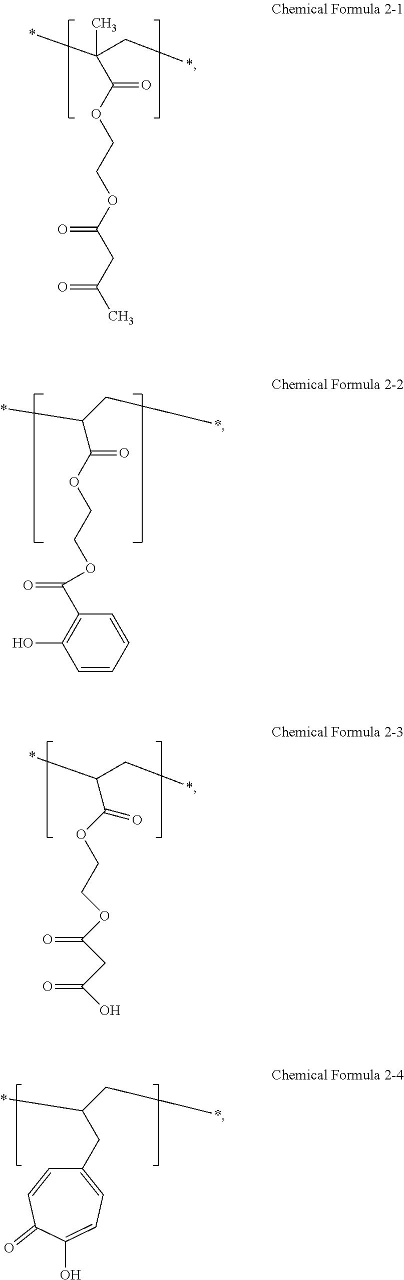

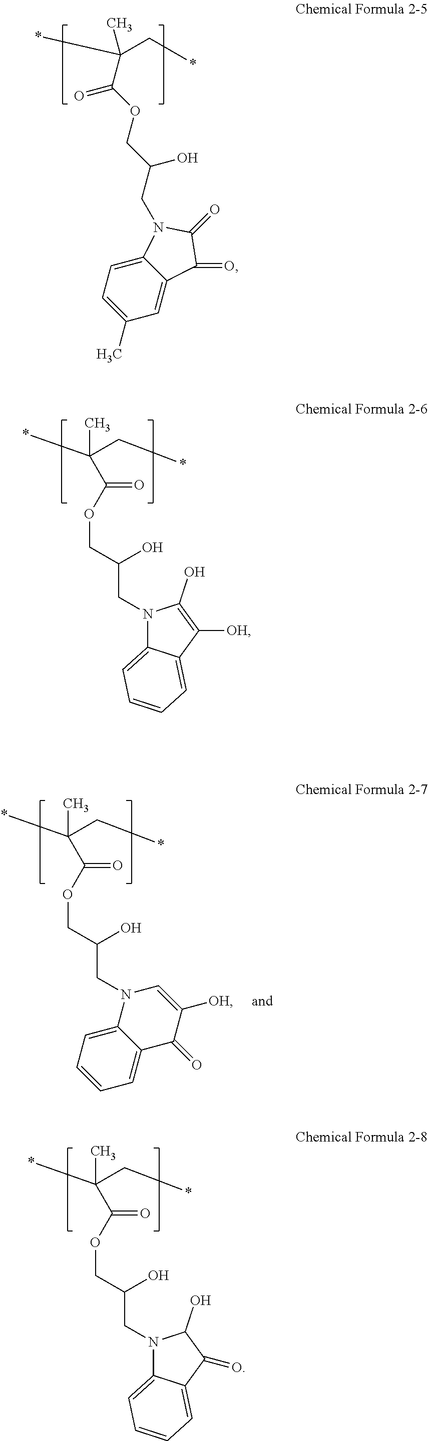

The polymer may have a weight average molecular weight (M_{w}) of about 1,000 g/mol to about 300,000 g/mol, for example, about 3,000 g/mol to about 200,000 g/mol, for example, about 3,000 g/mol to about 100,000 g/mol, for example, about 3,000 g/mol to about 90,000 g/mol, for example, about 3,000 g/mol to about 70,000 g/mol, for example, about 3,000 g/mol to about 50,000 g/mol, for example, about 5,000 g/mol to about 50,000 g/mol, for example, about 5,000 g/mol to about 30,000 g/mol, but embodiments of the present disclosure are not limited thereto. By having a weight average molecular weight within the foregoing ranges, a carbon content (e.g., amount) and solubility in the solvent of the resist underlayer composition including the polymer may be adjusted and improved (or enhanced) or optimized.

The polymer may be included in an amount of about 0.1 wt % to about 50 wt % based on a total weight (e.g., based on 100 wt %) of the resist underlayer composition. For example, the polymer may be included in an amount of about 0.05 wt % to about 40 wt %, about 0.05 wt % to about 30 wt %, about 0.05 wt % to about 20 wt %, about 0.1 wt % to about 40 wt %, for example, about 0.1 wt % to about 30 wt %, for example, about 0.1 wt % to about 20 wt %, for example, about 0.2 wt % to about 20 wt % based on a total weight (e.g., based on 100 wt %) of the resist underlayer composition, but embodiments of the present disclosure are not limited thereto. By including the polymer within the foregoing ranges in the composition, the thickness, surface roughness, and a degree of planarization of the resist underlayer may be adjusted and improved (or enhanced) or optimized.

The resist underlayer composition according to one or more embodiments may include a solvent. The solvent is not particularly limited as long as it has sufficient or suitable solubility and/or dispersibility for the polymer and compound according to one or more embodiments, but may be, for example, propylene glycol, propylene glycol diacetate, methoxypropanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, N-methylpyrrolidone, methyl 2-hydroxyisobutyrate, acetylacetone, ethyl 3-ethoxypropionate, or a combination thereof, but embodiments of the present disclosure are not limited thereto.

The resist underlayer composition according to one or more embodiments may further include one or more polymers selected from among an acrylic resin, an epoxy resin, a novolac-based resin, a glycoluril-based resin, and a melamine-based resin, in addition to the polymer and solvent as described in one or more embodiments, but embodiments of the present disclosure are not limited thereto.

The resist underlayer composition according to one or more embodiments may further include an additive including a surfactant, a thermal acid generator, a plasticizer, or a combination thereof.

The surfactant may be utilized to improve coating defects (or reduce a degree or occurrence of coating defects) caused by an increase in a solid content (e.g., amount) if (e.g., when) forming the resist underlayer, and may be, for example, an alkylbenzenesulfonate salt, an alkylpyridinium salt, polyethylene glycol, a quaternary ammonium salt, and/or the like, but embodiments of the present disclosure are not limited thereto.

The thermal acid generator may be an acidic compound, such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, or/and benzointosylate, 2-nitrobenzyltosylate, and other organic sulfonic acid alkylester may be used, but embodiments of the present disclosure are not limited thereto.

The plasticizer is not particularly limited, and one or more suitable plasticizers may be used. Examples of a plasticizer may include low molecular weight compounds, such as phthalic acid esters, adipic acid esters, phosphoric acid esters, trimellitic acid esters, citric acid esters, and/or the like, polyether compounds, polyester-based compounds, polyacetal compounds, and/or the like.

The additive may be included in an amount of about 0.001 parts to about 40 parts by weight based on 100 parts by weight of the resist underlayer composition. Within the foregoing ranges, solubility may be improved or enhanced while optical properties of the resist underlayer composition are not changed.

According to one or more embodiments, a resist underlayer manufactured using the resist underlayer composition as described in one or more embodiments is provided. The resist underlayer may be formed by coating the resist underlayer composition as described in one or more embodiments on, for example, a substrate and then curing through a heat treatment process.

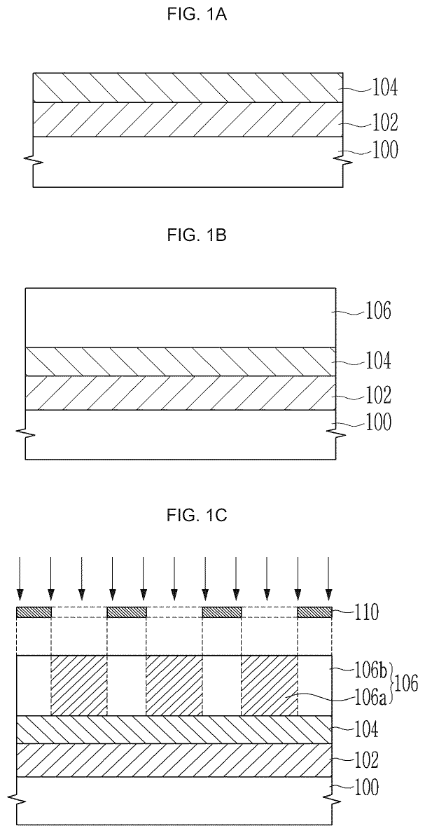

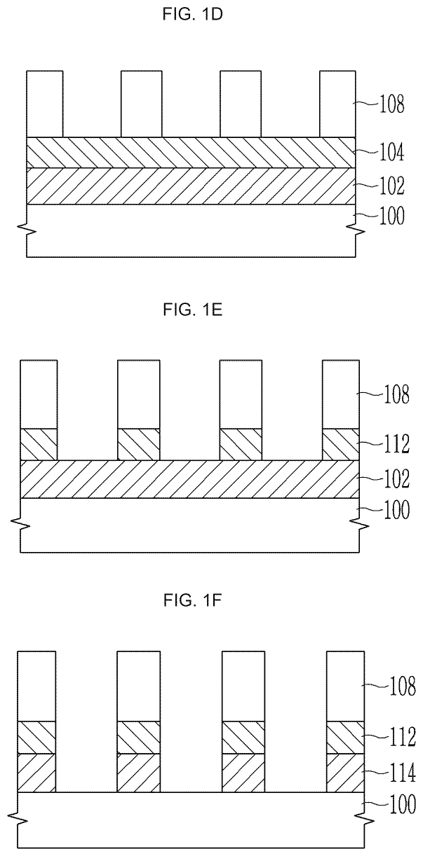

Hereinafter, a method of forming a pattern utilizing the resist underlayer composition as described in one or more embodiments is described in more detail with reference to FIGS. 1A to 1F. FIGS. 1A to 1F are cross-sectional views illustrating a method of forming a pattern utilizing the resist underlayer composition according to the present disclosure.

Referring to FIG. 1A, an etching target may be prepared. The etching target may be a thin film 102 formed on a semiconductor substrate 100. Hereinafter, the etching target may be limited to the thin film 102. A surface of the thin film 102 may be washed to remove impurities and/or the like remaining thereon. The thin film 102 may be, for example, a silicon nitride layer, a polysilicon layer, and/or a silicon oxide layer.

Subsequently, the resist underlayer composition as described in one or more embodiments may be coated on the surface of the cleaned thin film 102 by applying a spin coating method.

Then, the coated composition may be dried and baked to form a resist underlayer 104 on the thin film 102. The baking may be performed at about 100° C. to about 500° C., for example, about 100° C. to about 300° C. For example, the resist underlayer composition is described herein in more detail and thus will not be provided.

Referring to FIG. 1B, a photoresist film 106 may be formed by coating a photoresist on the resist underlayer 104.

Examples of the photoresist may include a positive photoresist including a naphthoquinone diazide compound and/or a novolac resin, a chemically amplified positive photoresist including an acid generator capable of dissociating an acid upon exposure, a compound that decomposes in the presence of an acid to increase or enhance solubility in an alkaline aqueous (e.g., water-soluble) solution, and/or an alkali-soluble resin, a chemically amplified positive photoresist including an acid generator and/or an alkali-soluble resin having a group capable of imparting a resin that decomposes in the presence of an acid to increase or enhance solubility in an alkaline aqueous (e.g., water-soluble) solution, and/or the like.

Next, a first baking process may be performed to heat the substrate 100 on which the photoresist film 106 is formed. The first baking process may be performed at a temperature of about 90° C. to about 120° C.

Referring to FIG. 1C, the photoresist film 106 may be selectively exposed. Exposure of the photoresist film 106 may be, for example, performed by positioning an exposure mask having a set or predetermined pattern on a mask stage of an exposure apparatus and aligning the exposure mask 110 on the photoresist film 106. Subsequently, a set or predetermined region of the photoresist film 106 on the substrate 100 may selectively react with light passing the exposure mask by radiating light into the exposure mask 110.

For example, the light used during the exposure may include short wavelength light, such as an i-line having a wavelength of about 365 nm, a KrF excimer laser having a wavelength of about 248 nm, and/or an ArF excimer laser having a wavelength of about 193 nm. In one or more embodiments, EUV (extreme ultraviolet) having a wavelength of about 13.5 nm corresponding to extreme ultraviolet light may be used.

The photoresist film 106a of the exposed region may become relatively hydrophilic compared to the photoresist film 106b of the unexposed region. Accordingly, the photoresist films of the exposed region 106a and the unexposed region 106b may have different solubilities.

Next, a second baking process may be performed on the substrate 100. The second baking process may be performed at a temperature of about 90° C. to about 150° C. By performing the second baking process, the photoresist film corresponding to the exposed region may become easily or suitably soluble in a specific solvent.

Referring to FIG. 1D, for example, by dissolving and then removing the photoresist film 106a corresponding to the exposed region using tetra-methyl ammonium hydroxide (TMAH) and/or the like, the photoresist film 106b remaining after development may form a photoresist pattern 108.

Subsequently, the resist underlayer 104 may be etched utilizing the photoresist pattern 108 as an etch mask. An organic film pattern 112 as illustrated in FIG. 1E may be formed through the etching process as described in one or more embodiments. The etching may be, for example, dry etching using etching gas, and the etching gas may be, for example, CHF₃, CF₄, Cl₂, O₂, and a mixed gas thereof. As described in one or more embodiments, because the resist underlayer formed by the resist underlayer composition according to one or more embodiments has a fast etch rate, a smooth etching process may be performed within a short time.

Referring to FIG. 1F, the photoresist pattern 108 may be applied as an etching mask to etch the exposed thin film 102. As a result, the thin film may be formed into a thin film pattern 114. In the exposure process performed previously, a thin film pattern 114 formed by an exposure process performed using a short wavelength light source, such as an i-line (a wavelength of about 365 nm), a KrF excimer laser (a wavelength of about 248 nm), and/or an ArF excimer laser (a wavelength of about 193 nm), may have a width ranging from tens to hundreds of nanometers (nm), and the thin film pattern 114 formed by the exposure process performed using the EUV light source may have a width of less than or equal to about 20 nm.

Hereinafter, one or more embodiments of the present disclosure are described in more detail through Examples regarding synthesis of the polymer and preparation of a resist underlayer composition including the polymer. However, embodiments of the present disclosure are not restricted by the following examples. Synthesis of Polymer Synthesis Example 1

In a 500 mL 3-neck round bottom flask, 42.77 g of 2,6-diiodo-4-vinylphenol, 24.64 g of (2-acetoacetoxy)ethyl methacrylate (TCI), 1.9 g of dimethyl 2,2′-azobis(2-methylpropionate) (V-601; TCI Inc.), and 70 g of propylene glycol methyl ether acetate (PGMEA) were added to prepare a reaction solution, and a condenser was connected thereto. The reaction solution was heated at 100° C. for 5 hours to proceed with a reaction and then, cooled to room temperature. Subsequently, the reaction solution was added dropwise to a beaker including 450 g of heptane, while stirring, to produce a gum, which was dissolved in 90 g of PGMEA. Finally, a polymer composed of structural units represented by Chemical Formula 1-1 and Chemical Formula 2-1 was obtained. (M_{w}: 4,400 g/mol)

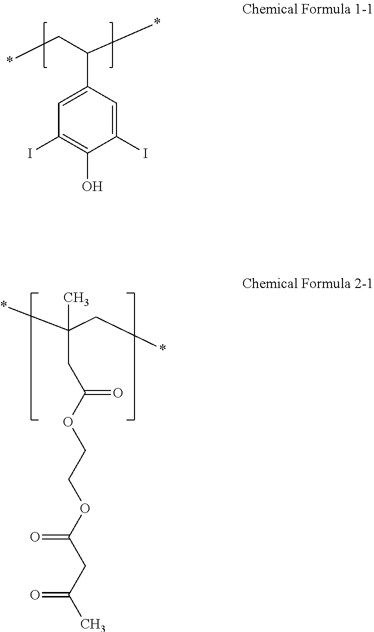

### Synthesis Example 2

In a 100 mL 2-neck round bottom flask, 42.77 g of 2,6-diiodo-4-vinylphenol, 27.17 g of benzoic acid, 2-hydroxy-, 2-[(1-oxo-2-propenyl)oxy]ethyl ester (Angene Chemical), 1.9 g of dimethyl 2,2′-azobis (2-methylpropionate) (V-601; TCI), and 70 g of (propylene glycol methyl ether acetate, PGMEA) were added to prepare a reaction solution ion, and a condenser was connected thereto. The reaction solution was heated at 100° C. for 5 hours to proceed with a reaction and then, cooled to room temperature. Subsequently, the reaction solution was added dropwise to a beaker including 450 g of heptane, while stirring, to produce a gum, which was dissolved in 90 g of PGMEA. Finally, a polymer composed of structural units represented by Chemical Formula 1-1 and Chemical Formula 2-2 was obtained. (M_{w}: 6,100 g/mol)

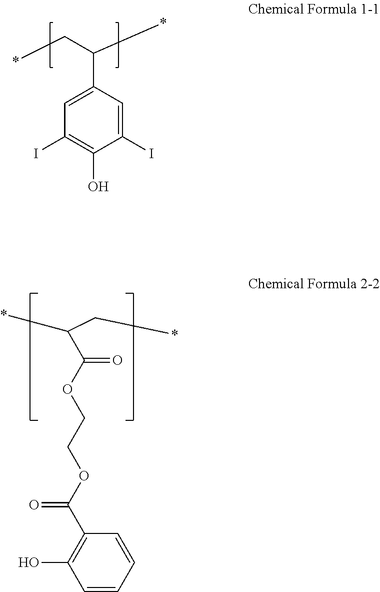

### Synthesis Example 3

In a 250 mL 2-neck round bottom flask, 19.65 g of 3-chloro-2-hydroxypropyl methacrylate, 16.1 g of 5-methylisatin, 0.02 g of dibutylhydroxytoluene (BHT), and 50 g of DMF were added to prepare a reaction solution and then, reacted at 90° C. The reaction solution was reacted for 5 hours, while stirring, and then, quenched with NH₄Cl to complete the reaction. The resultant was purified with water to complete the process to obtain a synthetic product composed of structural units represented by Chemical Formula 2-5.

Subsequently, in a 500 mL 2 neck round bottom flask, 57.5 g of a monomer represented by Chemical Formula 2-5, 43 g of 2,6-diiodo-4-vinylphenol, 2 g of dimethyl 2,2′-azobis(2-methylpropionate) (V-601; TCI Inc.), and 100 g of propylene glycol methyl ether acetate (PGMEA) were added to prepare a reaction solution, and a condenser was also prepared. The reaction solution was heated at 90° C. for 2 hours and then, added dropwise to a beaker containing 450 g of heptane, while stirring, to produce a gum, which was dissolved in 100 g of PGMEA to finally obtain a polymer composed of structural units represented by Chemical Formulas 1-1 and 2-5. (M_{w}: 7,600 g/mol)

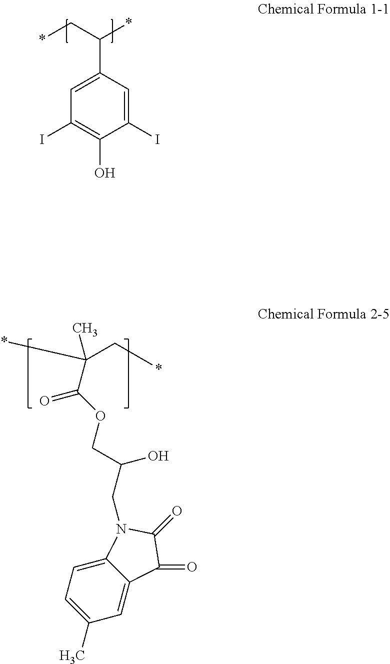

### Synthesis Example 4

In a 500 mL 3 neck round bottom flask, 42.8 g of 2,6-diiodo-4-vinylphenol, 24.6 g of (2-acetoacetoxy)ethyl methacrylate (TCI), 16.4 g of glycidyl methacrylate (TCI), 2 g of dimethyl 2,2′-azobis(2-methylpropionate) (V-601; TCI Inc.), and 85 g of propylene glycol methyl ether acetate (PGMEA) were added to prepare a reaction solution, and a condenser was connected thereto. The reaction solution was heated at 90° C. for 1 hour to proceed with a reaction and then, cooled to room temperature. Subsequently, the reaction solution was added dropwise to a beaker including 450 g of heptane, while stirring, to produce a gum, which was dissolved in 90 g of PGMEA. Finally, a polymer composed of structural units represented by Chemical Formulas 1-1, 2-1, and 4-1 was obtained. (M_{w}: 8,800 g/mol)

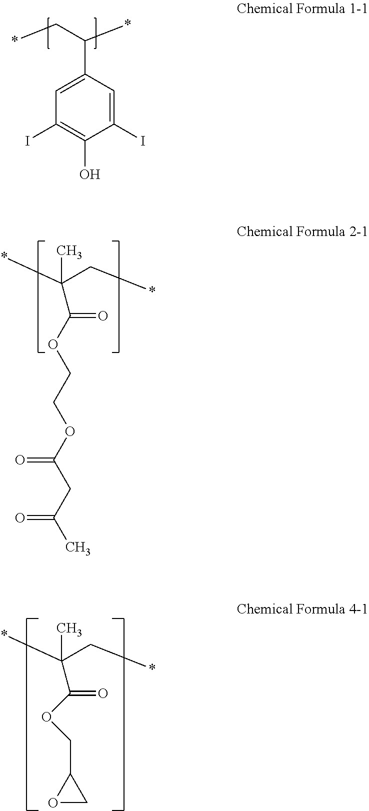

### Comparative Synthesis Example 1

In a 250 mL 3-neck round bottom flask, 20 g of methyl methacrylate, 3.5 g of dimethyl 2,2′-azobis(2-methylpropionate) (V-601; TCI Inc.), and 75 g of propylene glycol methyl ether acetate (PGMEA) were added to prepare a reaction solution, and a condenser was connected thereto. The reaction solution was heated at 75° C. for 3 hours to proceed with a reaction and then, cooled to room temperature. Subsequently, the reaction solution was added dropwise to a beaker including 450 g of heptane, while stirring, to produce a gum, which was dissolved in 90 g of PGMEA. Finally, a polymer composed of structural unit represented by Chemical Formula 5 was obtained. (M_{w}: 3,000 g/mol)

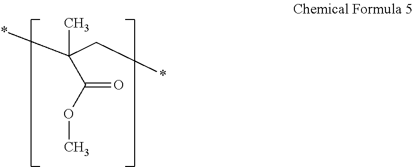

### Comparative Synthesis Example 2

In a 250 mL 3-neck round bottom flask, 28 g of glycidyl methacrylate (TCI), 3.2 g of dimethyl 2,2′-azobis(2-methylpropionate) (V-601; TCI Inc.), and 30 g of propylene glycol methyl ether acetate (PGMEA) were added to prepare a reaction solution, and a condenser was connected thereto. The reaction solution was heated at 85° C. for 2 hours to proceed with a reaction and then, cooled to room temperature. Subsequently, the reaction solution was added dropwise to a beaker containing 450 g of heptane, while stirring, to produce a gum, which was dissolved in 90 g of PGMEA. Finally, a polymer composed of structural unit represented by Chemical Formula 4-1 was obtained. (M_{w}: 3,500 g/mol)

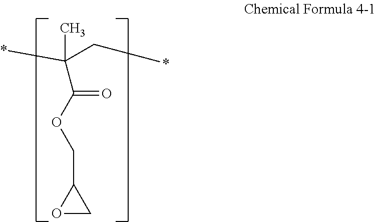

### Comparative Synthesis Example 3

In a 250 mL 3-neck round bottom flask, 75 g of 2,6-diiodo-4-vinylphenol, 3.3 g of dimethyl 2,2′-azobis(2-methylpropionate) (V-601; TCI Inc.), and 75 g of propylene glycol methyl ether acetate (PGMEA) were added to prepare a reaction solution, and a condenser was connected thereto. The reaction solution was heated at 90° C. for 3 hours to proceed with a reaction and then, cooled to room temperature. Subsequently, the reaction solution was added dropwise to a beaker including 450 g of heptane, while stirring, to produce a gum, which was dissolved in 90 g of PGMEA. Finally, a polymer composed of structural unit represented by Chemical Formula 1-1 was obtained. (M_{w}: 3,400 g/mol)

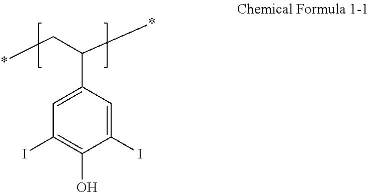

### Preparation of Resist Underlayer Compositions

### Examples 1 to 4 and Comparative Examples 1 to 3

Each resist underlayer composition according to Examples 1 to 4 and Comparative Examples 1 to 3 was prepared by completely dissolving 1.2 g of each of the polymers of Synthesis Examples 1 to 4 and Comparative Synthesis Examples 1 to 3, 0.4 g of PL1174 (a crosslinking agent), and 0.04 g of ammonium triflate (AOTf) in 15 g of propylene glycol monomethylether and diluting the solution with an additional solvent to include 0.45 wt % of the polymer based on its total weight (e.g., based on 100 wt %) of the resist underlayer composition).

### Evaluation 1: Exposure Characteristics Evaluation

The compositions according to Examples 1 to 4 and Comparative Examples 1 to 3 were respectively coated in a spin-on coating method and then, heat-treated on a hot plate at 205° C. for 60 seconds to form a 50 Å-thick resist underlayer. Subsequently, on this underlayer, each of the photoresist solution was coated in the spin-on coating method and then, heat-treated on the hot plate at 110° C. for 1 minute to form a photoresist layer. The photoresist layer was exposed under a condition of a line with a width of 30 nm and a space with a width of 30 nm between the lines by using an e-beam light exposer (acceleration voltage of 100 keV, Elionix Inc.). Subsequently, the photoresist layer was developed in a 2.38 mass % TMAH aqueous solution and rinsed with pure water for 15 seconds to form a 50 nm line and space (US) photoresist pattern. Then, the photoresist pattern was evaluated with respect to optimum energy.

### Evaluation 2: Line Width Roughness (LWR) Evaluation

Each of the compositions of Examples 1 to 4 and Comparative Examples 1 to 3 was spin-on coated and then, heat-treated at 205° C. on a hot plate for 60 seconds to form a 50 Å-thick resist underlayer. Subsequently, on the underlayer, a photoresist solution was spin-on coated and then, heat-treated at 110° C. on the hot plate for 1 minute to form a photoresist layer. The resist layer was exposed under conditions of a line width of 30 nm and a line space width of 30 nm by using an e-beam exposer (an acceleration voltage: 100 keV, manufactured by Elionix). Subsequently, the exposed resist layer was heat-treated at 95° C. for 60 seconds, developed with a 2.38 wt % tetramethylammonium hydroxide (TMAH) aqueous solution for 60 seconds, and rinsed with pure water for 15 seconds to form a resist pattern.

The formed pattern was examined with respect to pattern collapse with a scanning electron microscope (SEM) S-9260 (Hitachi, Ltd.) to give X, if (e.g., when) the pattern collapse was observed, but 0, if (e.g., when) the pattern collapse was not observed in Table 1.

The pattern with a width of 30 nm was examined with respect to line width roughness (LWR) with the scanning electron microscope (SEM) S-9260 (Hitachi, Ltd.) to measure a distance from a reference line where the edge should be within an edge range of 2 μm along a length of the pattern. The results are shown in Table 1, wherein the smaller the line width roughness (LWR), the better the characteristics.

The examples and the comparative examples were evaluated with respect to an exposure dose, which was converted into a ratio based on 100% of that of Comparative Example 3, and in addition, the LWRs of the examples and the comparative examples were converted to a ratio based on 100% of that of Comparative Example 2, and the results are shown in Table 1. The smaller exposure dose and line width roughness (LWR), the better pattern formality and sensitivity.

TABLE 1

| | Exposure dose | Pattern collapse | |
|---|---|---|---|
| | (Eop, %) | or not | LWR (nm) |
| Example 1 | 95% | X | 82% |
| Example 2 | 94% | X | 89% |
| Example 3 | 91% | X | 91% |
| Example 4 | 96% | X | 87% |
| Comparative Example 1 | 107% | ◯ | 108% |
| Comparative Example 2 | 104% | ◯ | 100% |
| Comparative Example 3 | 100% | Δ | 115% |

Referring to Table 1, the resist underlayers of Examples 1 to 4 exhibit excellent or suitable fine pattern (50 nm L/S) formality and sensitivity, compared with those of Comparative Examples 1 to 3. Also, the resist underlayers of Examples 1 to 4 have smaller LWR than those of Comparative Examples 1 to 3, resulting in having more substantially uniform patterns.

A pattern forming device, a semiconductor forming device, and/or any other relevant devices or components according to one or more embodiments of the present disclosure may be implemented utilizing any suitable hardware, firmware (e.g., an application-specific integrated circuit), software, or a combination of software, firmware, and hardware. For example, the one or more suitable components of the device may be formed on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components for performing the one or more suitable functionalities as described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, a flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the present disclosure.

Hereinbefore, certain embodiments of the present disclosure have been described and illustrated, however, it should be apparent to a person having ordinary skill in the art that the present disclosure is not limited to the embodiments as described and may be suitably modified and transformed without departing from the spirit and scope of the present disclosure. Accordingly, the modified or transformed embodiments as such may not be understood separately from the technical ideas and aspects of one or more embodiments of the present disclosure, and the modified embodiments may be within the scope of the appended claims and equivalents thereof of the present disclosure.

### REFERENCE NUMERALS

Reference Numerals

| | |
|---|---|
| 100: substrate | 102: thin film |
| 104: resist underlayer | 106: photoresist film |
| 106a: exposed region | 106b: unexposed region |
| 108: photoresist pattern | 110: mask |
| 112: organic film pattern | 114: thin film pattern |

What is claimed is:

1. A resist underlayer composition, comprising:
a polymer comprising:
a structural unit represented by Chemical Formula 1; and
a structural unit represented by Chemical Formula 2; and
a solvent: 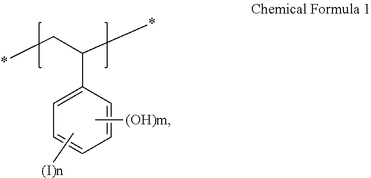
wherein, in Chemical Formula 1,
m is one of integers of 1 to 4,
n is one of integers of 1 to 4,
m+n is an integer less than or equal to 5, and
* is a linking point; 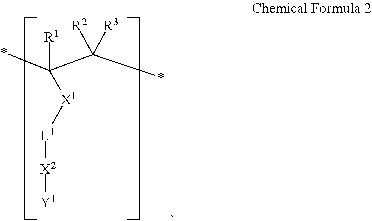
wherein, in Chemical Formula 2,
L¹ is a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C3 to C20 heterocycloalkylene group, a substituted or unsubstituted C6 to C20 arylene group, or a combination thereof,
X¹ and X² are each independently a single bond, —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ is a group represented by Chemical Formula 3,
R¹ to R³ are each independently hydrogen, deuterium, or a substituted or unsubstituted C1 to C10 alkyl group, and
* is a linking point: 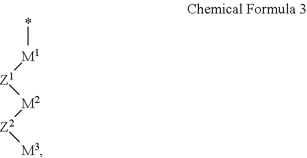
and
wherein, in Chemical Formula 3,
M¹ is a single bond, a substituted or unsubstituted C1 to C20 alkylene group, a substituted or unsubstituted C2 to C20 alkenylene group, —O—, —NH—, or a combination thereof,
Z¹ and Z² are each independently —C(═O)— or —CH(OH)—,
M² is a single bond, a double bond, *—C(R^{b})* (wherein, R^{b} is hydrogen, deuterium, or a C1 to C5 alkyl group, and * is a linking point with Z¹ or Z²), or a substituted or unsubstituted C1 to C3 alkylene group,
M³ is a hydroxyl group, a substituted or unsubstituted C1 to C20 alkyl group, a substituted or unsubstituted C2 to C20 alkenyl group, or a substituted or unsubstituted C6 to C20 aryl group,
M¹ and M³ or M² and M³ are optionally linked to each other to form a ring, and
* is a linking point.

2. The resist underlayer composition as claimed in claim 1, wherein, in Chemical Formula 1, m and n are each independently 1 or 2.

3. The resist underlayer composition as claimed in claim 1, wherein, in Chemical Formula 3,
L¹ is a single bond or a substituted or unsubstituted C1 to C10 alkylene group, and
X¹ and X² are each independently a single bond or —(CO)O—.

4. The resist underlayer composition as claimed in claim 1, wherein, in the polymer, a molar ratio of the structural unit represented by Chemical Formula 1 to the structural unit represented by Chemical Formula 2 is 9:1 to 1:9.

5. The resist underlayer composition as claimed in claim 1, wherein the polymer further comprises a structural unit represented by Chemical Formula 4: 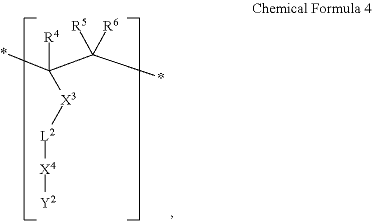
and
wherein, in Chemical Formula 4,
L² is a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X³ and X⁴ are each independently a single bond, —O—, —S—, —S(═O)—, —S(═O)₂—, —C(═O)—, —(CO)O—, —O(CO)O—, —C(═O)NH—, —NR^{c}— (wherein, R^{c} is hydrogen, deuterium, or a C1 to C10 alkyl group), or a combination thereof,
Y² is a hydroxyl group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, or a substituted or unsubstituted C6 to C20 aryl group,
R⁴ to R⁶ are each independently hydrogen, deuterium, or a substituted or unsubstituted C1 to C10 alkyl group, and
* is a linking point.

6. The resist underlayer composition as claimed in claim 5, wherein, in Chemical Formula 4,
L² is a single bond, a substituted or unsubstituted C1 to C10 alkylene group, or a substituted or unsubstituted C6 to C10 arylene group, X³ and X⁴ are each independently a single bond or —(CO)O—, and
Y² is a hydroxyl group, a substituted or unsubstituted C1 to C10 alkyl group, a substituted or unsubstituted C2 to C20 heterocycloalkyl group, or a substituted or unsubstituted C6 to C20 aryl group.

7. The resist underlayer composition as claimed in claim 1, wherein Chemical Formula 2 is represented by one or more selected from among Chemical Formula 2-1 to Chemical Formula 2-8:

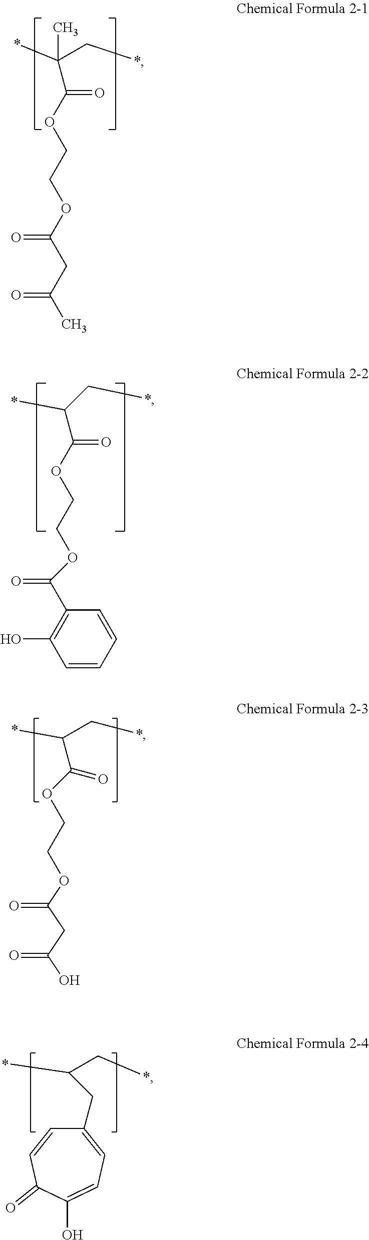

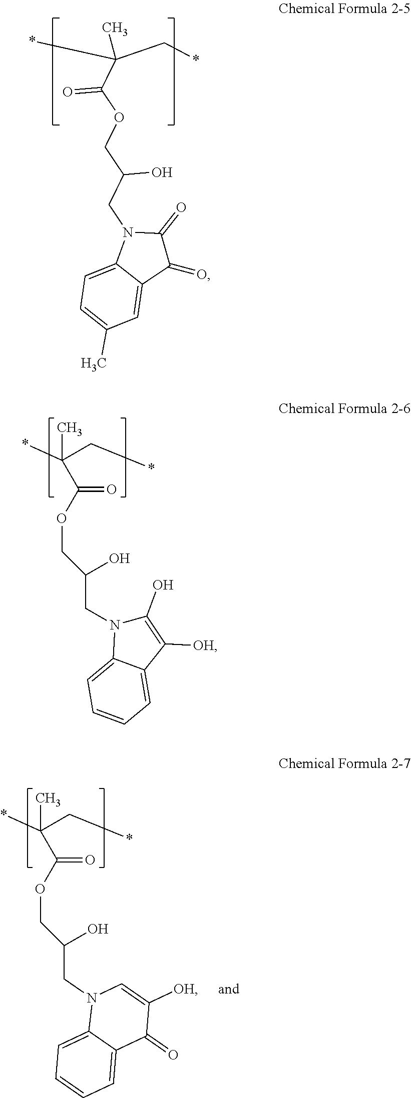

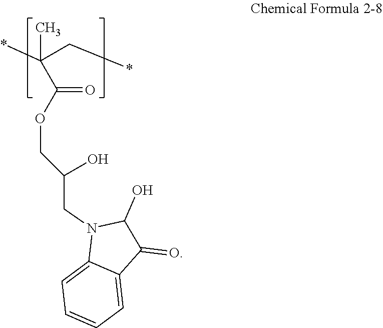

8. The resist underlayer composition as claimed in claim 1, wherein a weight average molecular weight of the polymer is 1,000 g/mol to 300,000 g/mol.

9. The resist underlayer composition as claimed in claim 1, wherein the polymer is included in an amount of 0.1 wt % to 50 wt % based on 100 wt % of the resist underlayer composition.

10. The resist underlayer composition as claimed in claim 1, further comprising one or more polymers selected from among an acrylic resin, an epoxy resin, a novolac-based resin, a glycoluril-based resin, and a melamine-based resin.

11. The resist underlayer composition as claimed in claim 1, further comprising an additive of a surfactant, a thermal acid generator, a photoacid generator, a plasticizer, or a combination thereof.

12. A method comprising:
forming an etching target layer on a substrate;
forming a resist underlayer by applying the resist underlayer composition as claimed in claim 1 on the etching target layer;
forming a photoresist pattern on the resist underlayer; and
sequentially etching the resist underlayer and the etching target layer utilizing the photoresist pattern as an etching mask,
wherein the method is a method of forming a pattern.

13. The method as claimed in claim 12, wherein, in Chemical Formula 1, m and n are each independently 1 or 2.

14. The method as claimed in claim 12, wherein, in Chemical Formula 3,
L¹ is a single bond or a substituted or unsubstituted C1 to C10 alkylene group, and
X¹ and X² are each independently a single bond or —(CO)O—.

15. The method as claimed in claim 12, wherein, in the polymer, a molar ratio of the structural unit represented by Chemical Formula 1 to the structural unit represented by Chemical Formula 2 is 9:1 to 1:9.

16. The method as claimed in claim 12, wherein the polymer further comprises a structural unit represented by Chemical Formula 4: 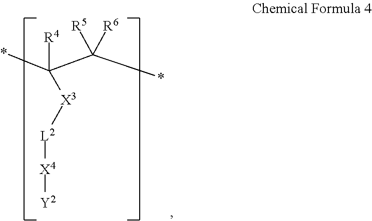
and
wherein, in Chemical Formula 4,
L² is a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X³ and X⁴ are each independently a single bond, —O—, —S—, —S(═O)—, —S(═O)₂—, —C(═O)—, —(CO)O—, —O(CO)O—, —C(═O)NH—, —NR^{c}— (wherein, R^{c} is hydrogen, deuterium, or a C1 to C10 alkyl group), or a combination thereof,
Y² is a hydroxyl group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, or a substituted or unsubstituted C6 to C20 aryl group,
R⁴ to R⁶ are each independently hydrogen, deuterium, or a substituted or unsubstituted C1 to C10 alkyl group, and
* is a linking point.

17. The resist underlayer as claimed in claim 16, wherein, in Chemical Formula 4,
L² is a single bond, a substituted or unsubstituted C1 to C10 alkylene group, or a substituted or unsubstituted C6 to C10 arylene group, X³ and X⁴ are each independently a single bond or —(CO)O—, and
Y² is a hydroxyl group, a substituted or unsubstituted C1 to C10 alkyl group, a substituted or unsubstituted C2 to C20 heterocycloalkyl group, or a substituted or unsubstituted C6 to C20 aryl group.

18. The resist underlayer as claimed in claim 13, wherein Chemical Formula 2 is represented by one or more selected from among Chemical Formula 2-1 to Chemical Formula 2-8:

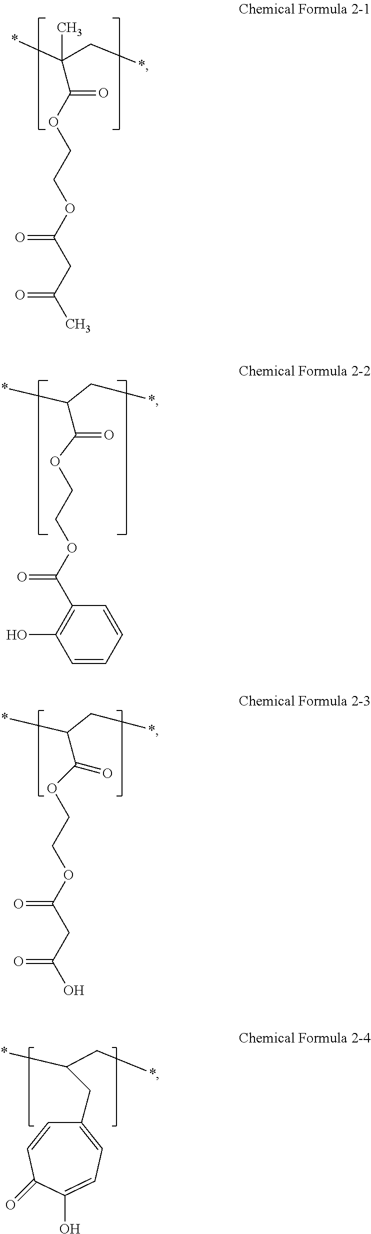

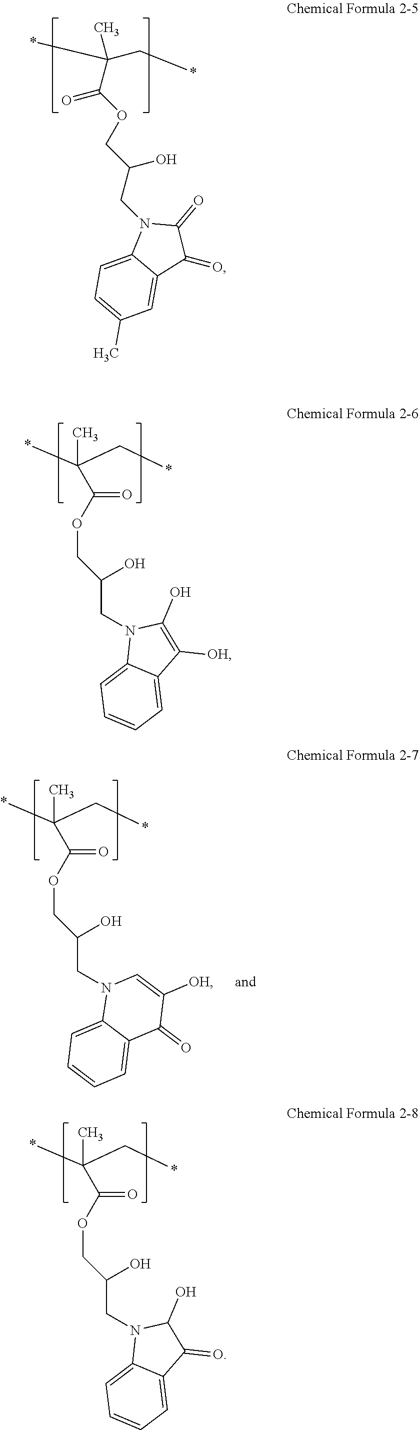

19. A system comprising:
means for forming an etching target layer on a substrate;
means for forming a resist underlayer by applying the resist underlayer composition as claimed in claim 1 on the etching target layer;
means for forming a photoresist pattern on the resist underlayer; and
means for sequentially etching the resist underlayer and the etching target layer utilizing the photoresist pattern as an etching mask,
wherein the system is a system of forming a pattern.

20. A resist underlayer of the resist underlayer composition as claimed in claim 1.
